(19) United States
(12) Patent Application Publication
(10) Pub. No.: US 2019/0267319 A1
(43) Pub. Date: Aug. 29, 2019

(54) RECONFIGURABLE INTERCONNECT ARRANGEMENTS USING THIN-FILM TRANSISTORS

(71) Applicant: Intel Corporation, Santa Clara, CA (US)

(72) Inventors: Abhishek A. Sharma, Hillsboro, OR (US); Jack T. Kavalieros, Portland, OR (US); Gilbert Dewey, Beaverton, OR (US); Willy Rachmady, Beaverton, OR (US); Ravi Pillarisetty, Portland, OR (US)

(73) Assignee: Intel Corporation, Santa Clara, CA (US)

(21) Appl. No.: 15/906,001

(22) Filed: Feb. 27, 2018

(51) Int. Cl. H01L 23/525; H01L 27/12; H01L 29/24; H01L 29/786

(52) U.S. Cl. CPC H01L 23/525; H01L 27/1207; H01L 27/2436; H01L 29/786; H01L 29/24

(57) ABSTRACT

Disclosed herein are reconfigurable interconnect arrangements that include thin-film transistors (TFTs). An exemplary arrangement includes a TFT provided over a semiconductor substrate, the arrangement including one or more metal interconnect layers between the TFT and the semiconductor substrate, as well as one or more metal interconnect layers provided over the side of the TFT that is opposite to the side facing the semiconductor substrate. Integrating a TFT in between the metal interconnect layers of an interconnect arrangement advantageously allows controlling electrical connectivity between various circuit elements by controlling voltages applied to a gate electrode of the TFT.

### TECHNICAL FIELD

This disclosure relates generally to the field of semiconductor devices, and more specifically, to interconnect arrangements used to connect various circuit elements of semiconductor devices.

### BACKGROUND

Multiple elements in an integrated circuit (IC) structure may be electrically connected by electrically conductive, typically metal, interconnects. Once manufactured, conventional interconnect arrangements are rigid, with no further modifications possible. Such conventional interconnect arrangements have been limited in their scalability in some application (e.g., some memory or logic applications).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a cross-sectional view of an exemplary reconfigurable interconnect arrangement with a thin-film transistor, in accordance with various embodiments of the present disclosure.

FIG. 2 illustrates a cross-sectional view of an exemplary electronic device implementing reconfigurable interconnect arrangement with a thin-film transistor, according to some embodiments of the present disclosure.

FIG. 3 illustrates a cross-sectional view of an exemplary electronic device implementing reconfigurable interconnect arrangement with a thin-film transistor, according to other embodiments of the present disclosure.

FIG. 4 is a flow diagram of an illustrative method of operating an electronic device using a reconfigurable interconnect arrangement with a thin-film transistor, according to some embodiments of the present disclosure.

FIGS. 5A and 5B are top views of a wafer and dies that may include any of the reconfigurable interconnect arrangements disclosed herein, in accordance with various embodiments.

FIG. 6 is a cross-sectional side view of an integrated circuit (IC) device that may include any of the reconfigurable interconnect arrangements disclosed herein, in accordance with various embodiments.

FIG. 7 is a cross-sectional side view of an IC device assembly that may include any of the reconfigurable interconnect arrangements disclosed herein, in accordance with various embodiments.

FIG. 8 is a block diagram of an example computing device that may include any of the reconfigurable interconnect arrangements disclosed herein, in accordance with various embodiments.

### DETAILED DESCRIPTION

Disclosed herein are reconfigurable interconnect arrangements that include thin-film transistors (TFTs). An exemplary arrangement includes a TFT provided over a semiconductor substrate, the arrangement including one or more metal interconnect layers between the TFT and the semiconductor substrate, as well as one or more metal interconnect layers provided over the side of the TFT that is opposite to the side facing the semiconductor substrate. Integrating a TFT in between the metal interconnect layers of an interconnect arrangement advantageously allows controlling electrical connectivity between various circuit elements by controlling voltages applied to a gate electrode of the TFT. For example, such a TFT may be used to connect storage elements, e.g. a dynamic random access memory (DRAM) element, a magnetic random access memory (MRAM) element, a resistive random access memory (RRAM) element, or a string of DRAM, MRAM, and/or RRAM elements, with selected front-end transistors.

TFT is a special kind of a field-effect transistor made by depositing a thin film of an active semiconductor material, as well as a dielectric layer and metallic contacts, over a supporting, typically non-conducting layer. At least a portion of the active semiconductor material forms a channel of the TFT. This is different from conventional, non-thin-film transistors where the active semiconductor channel material is typically a part of a substrate, e.g. a part of a silicon wafer. Embodiments of the present disclosure utilize this unique structure of a TFT to provide reconfigurable interconnect arrangements.

Reconfigurable interconnect arrangements with TFTs as described herein may be implemented to provide electrical connectivity between various components within or associated with an integrated circuit (IC). In various embodiments, components within or associated with an IC include, for example, transistors, diodes, storage elements, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

In the drawings, some schematic illustrations of exemplary structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

In the following detailed description, various aspects of the illustrative implementations will be described using terms commonly employed by those skilled in the art to convey the substance of their work to others skilled in the art. For example, the terms “oxide,” “carbide,” “nitride,” etc. refer to compounds containing, respectively, oxygen, carbon, nitrogen, etc. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

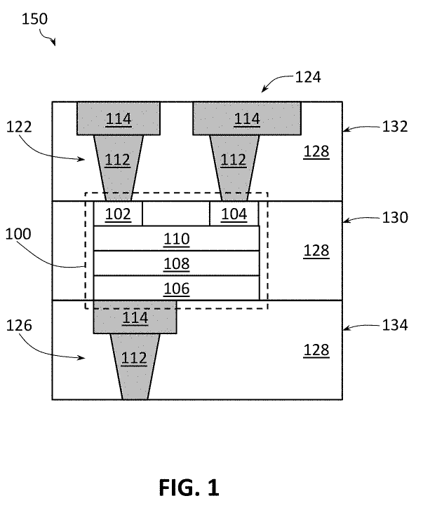

FIG. 1 illustrates a cross-sectional view of an exemplary reconfigurable interconnect arrangement 150 with a TFT 100, in accordance with various embodiments of the present disclosure. The TFT 100 may include a first source/drain (S/D) electrode 102, a second S/D electrode 104, a gate electrode 106, a gate dielectric 108, and a channel material 110 disposed between the gate dielectric 108 and the S/D electrodes 102 and 104.

The channel material 110 may be composed of semiconductor material systems including, for example, n-type or p-type materials systems. In some embodiments, the channel material 110 may include a high mobility oxide semiconductor material, such as tin oxide, antimony oxide, indium oxide, indium tin oxide, titanium oxide, zinc oxide, indium zinc oxide, indium gallium zinc oxide, gallium oxide, titanium oxynitride, ruthenium oxide, or tungsten oxide. In general, the channel material 110 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, n- or p-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In particular, the channel 110 may be formed of a thin film material. Some such materials may be deposited at relatively low temperatures, which makes them depositable within the thermal budgets imposed on back-end fabrication to avoid damaging the front-end components. In some embodiments, the channel material 110 may have a thickness between about 5 and 30 nanometers, including all values and ranges therein.

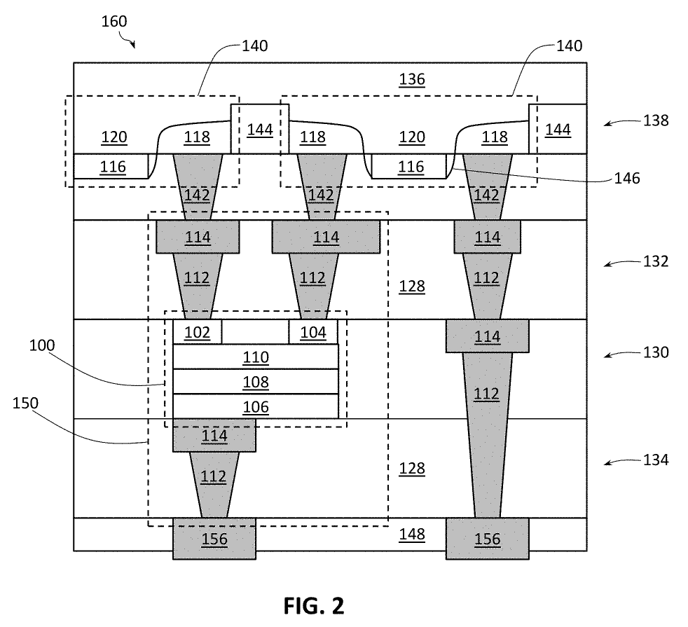

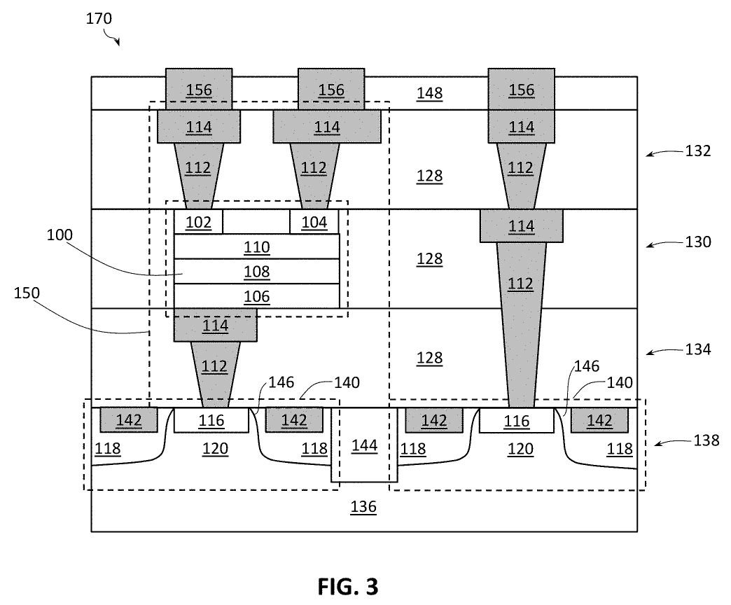

The S/D electrodes 104, 106, where designation of which electrode is a “source” electrode and which electrode is a “drain” electrode may vary (i.e. in some embodiments the first S/D electrode 102 may be a source electrode and the second S/D electrode 104 may be a drain electrode, while in other embodiments the first S/D electrode 102 may be a drain electrode and the second S/D electrode 104 may be a source electrode), may include any suitable electrically conductive material, alloy, or a stack of multiple electrically conductive materials. In some embodiments, the S/D electrodes 104, 106 may include one or more metals or metal alloys, with metals e.g., copper, ruthenium, palladium, platinum, cobalt, nickel, hafnium, zirconium, titanium, tantalum, and aluminum, tantalum nitride, titanium nitride, tungsten, doped silicon, doped germanium, or alloys and mixtures of these. In some embodiments, the S/D electrodes 104, 106 may include one or more electrically conductive alloys, oxides, or carbides of one or more metals. In some embodiments, the S/D electrodes 102 and/or 104 may include a doped semiconductor, such as silicon or another semiconductor doped with an n-type dopant or a p-type dopant. When the S/D electrodes 102 and/or 104 include a doped material, the materials used for the S/D electrodes 102 and/or 104 may take the form of any of the S/D regions 118 discussed below with reference to FIGS. 2 and 3. Metals may provide higher conductivity, while doped semiconductors may be easier to pattern during fabrication. In some embodiments, the S/D electrodes 104, 106 may have a thickness between about 2 nanometers and 1000 nanometers, preferably between about 2 nanometers and 100 nanometers. The S/D electrodes 102, 104 may, interchangeably, be referred to as “S/D terminals” or “S/D contacts.”

A gate dielectric 108 may laterally surround the channel 110, and the gate electrode 106 may laterally surround the gate dielectric 108 such that the gate dielectric 108 is disposed between the gate electrode 106 and the channel 110. The TFT 100 may be a bottom-gate transistor because the gate electrode 106 may be provided closer to a substrate over which the TFT 100 may be implemented (substrate not specifically shown in FIG. 1 but shown e.g. in FIGS. 2-3) than the S/D electrodes 102, 104.

The gate dielectric 108 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 108 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 108 during manufacture of the TFT 100 to improve the quality of the gate dielectric 108. In some embodiments, the gate dielectric 108 may have a thickness between about 0.5 nanometers and 3 nanometers, including all values and ranges therein, e.g., between about 1 and 3 nanometers, or between about 1 and 2 nanometers.

In some embodiments, the gate dielectric 108 may be a multilayer gate dielectric, e.g., it may include any of the high-k dielectric materials in one layer and a layer of IGZO. In some embodiments, the gate stack (i.e., a combination of the gate dielectric 108 and the gate electrode 106) may be arranged so that the IGZO is disposed between the high-k dielectric and the channel material 110. In such embodiments, the IGZO may be in contact with the channel material 110, and may provide the interface between the channel material 110 and the remainder of the multilayer gate dielectric 108. The IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10).

The gate electrode material 106 may include at least one p-type work function metal or n-type work function metal, depending on whether the TFT 100 is a P-type metal oxide semiconductor (PMOS) transistor or an N-type metal oxide semiconductor (NMOS) transistor. For a PMOS transistor, metals that may be used for the gate electrode material 106 may include, but are not limited to, ruthenium, palladium, platinum, cobalt, nickel, and conductive metal oxides (e.g., ruthenium oxide). For an NMOS transistor, metals that may be used for the gate electrode material 106 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 106 may consist of a stack of two or more metal layers, where one or more metal layers are work function metal layers and at least one metal layer is a fill metal layer. Further metal layers may be included for other purposes, such as to act as a barrier layer.

As shown in FIG. 1, the first S/D electrode 102 is in contact with a conductive pathway 122 that may route electrical signals to and/or from the first S/D electrode 102. Similarly, the second S/D electrode 104 is in contact with a conductive pathway 124 that may route electrical signals to and/or from the second S/D electrode 104, while the gate electrode 106 is in contact with a conductive pathway 126 that may route electrical signals to and/or from the gate electrode 106. In FIG. 1, each of the conductive pathways 122, 124, and 126 is illustrated as including a conductive via 112 and a conductive line 114. However, the arrangement of conductive lines and vias in the conductive pathways 122, 124, and 126 shown in FIG. 1 is simply illustrative, and any suitable interconnect arrangement of one or more conductive vias and/or lines may be used to form each of the conductive pathways 122, 124, and 126. For example, in some embodiments, any of the conductive pathways 122, 124, and 126 may include the conductive line 114 which directly contacts the respective electrode 102, 104, or 106, without an intervening conductive via 112. In another example, in some embodiments, any of the conductive pathways 122, 124, and 126 may include only one or more conductive vias 112, without any conductive lines 114.

An insulating material 128 may be disposed around the TFT 100 and the conductive pathways 122, 124, 126 of FIG. 1, as shown. The insulating material 128 may be a dielectric material, such as silicon dioxide. In some embodiments, the insulating material 128 may include any suitable interlayer dielectric (ILD) material such as silicon oxide, silicon nitride, aluminum oxide, and/or silicon oxynitride.

Conductive pathways on one side of the TFT 100, e.g. the conductive pathways 122 and 124, may be considered as metal interconnects of an interconnect layer 132, while conductive pathways on the opposite side of the TFT, e.g. the conductive pathway 126, may be considered as metal interconnects of a different metal interconnect layer, 134. The TFT 100 itself may be considered to be included in a layer 130 that is sandwiched between the interconnect layers 132 and 134, as shown in FIG. 1. Although FIG. 1 illustrates that each of the layers 130, 132, and 134 includes the insulating material 128, in various embodiments, the type of the insulating material 128 includes in each or in at least some of these layers may be different.

Embedding the TFT 100 within a metal interconnect stack, e.g. between at least two different metal interconnect layers as shown in FIG. 1, allows controlling electrical connectivity between various further circuit components by controlling the TFT 100. For example, by controlling signal, e.g. voltage, applied to the gate electrode 106 of the TFT 100, e.g. using the conductive pathway 126, the conductive pathways 122 and 124 may be connected or disconnected, as desired. Consequently, further circuit components coupled to the conductive pathways 122 and 124 may be connected or disconnected, as desired. For example, for logic implementations, further circuit components could be various transistors, while, in another example, for memory implementations, further circuit components could be storage elements, such as one or more of DRAM, MRAM, or RRAM elements, etc. Still, in further implementations, the TFT 100 may be used to connect or disconnect storage elements, e.g. one or more of DRAM, MRAM, or RRAM elements, or a string of DRAM, MRAM, and/or RRAM elements, with selected front-end transistors, which may e.g. be used to augment a memory array by adding redundant bits if any of the array bits are non-functional due to e.g. defects. FIGS. 2 and 3 illustrate various embodiments where the reconfigurable interconnect 150 with the TFT 100 is used to selectively couple two transistors labeled in these FIGS. as transistors 140, but, as specified above, embodiments of the present disclosure are not limited to circuitry interconnected by the TFT 100 being in the form of such transistors.

Reconfigurable interconnect arrangements 150 with TFTs 100 as described above may be included in any suitable electronic device structures. FIG. 2 illustrates a cross-sectional view of an exemplary electronic device 160 implementing a reconfigurable interconnect arrangement with a TFT, according to some embodiments of the present disclosure, while FIG. 3 illustrates a cross-sectional view of an exemplary electronic device 170 implementing a reconfigurable interconnect arrangement with a TFT, according to other embodiments of the present disclosure. In each of FIGS. 2 and 3, the reconfigurable interconnect arrangement with the TFT may be the reconfigurable interconnect arrangement 150 with the TFT 100 as shown in and described with reference to FIG. 1, which descriptions, therefore, are not repeated in the interests of brevity. Any of the embodiments of the components of the reconfigurable interconnect arrangement 150 illustrated in FIG. 1 (e.g., the conductive vias 112, the conductive lines 114, and various conductive pathways shown in FIG. 1) may be included in any of the electronic devices disclosed herein (e.g., the electronic devices 160, 160 discussed with reference to FIGS. 2 and 3).

In both FIGS. 2 and 3, the reconfigurable interconnect arrangement 150 is used to selectively connect transistors 140. As discussed in detail below, the transistors 140 may be a “front-end” transistors (i.e., formed as part of front-end fabrication operations), while the TFT 100 of the reconfigurable interconnect arrangement 150 may be a “back-end” transistor (i.e., formed as part of back-end fabrication operations). FIGS. 2 and 3 differ in which side of the TFT 100 is connected to one or more of the transistors 140. Namely, in the embodiment shown in FIG. 2, it is the S/D electrodes 102, 104 of the TFT 100 that are electrically connected to parts of two different transistors 140, while, in the embodiment shown in FIG. 3, it is the gate electrode 106 of the TFT 100 that is electrically connected to one of the transistors 140.

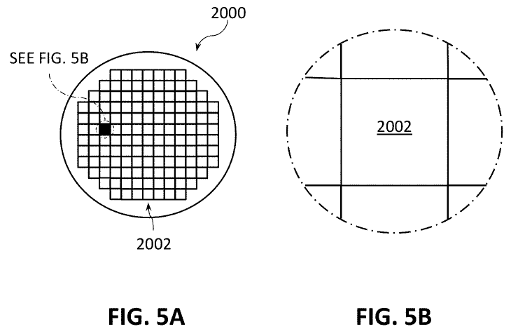

The electronic devices 160, 170 may be formed on a substrate 136 (e.g., the wafer 2000 of FIG. 5A, discussed below) and may be included in a die (e.g., the singulated die 2002 of FIG. 5B, discussed below). The substrate 136 may be a semiconductor substrate composed of semiconductor material systems including, for example, n-type or p-type material systems. The substrate 136 may include, for example, a crystalline substrate formed using a bulk silicon or a silicon-on-insulator substructure. In some embodiments, the substrate 136 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the substrate 136. Although a few examples of materials from which the substrate 136 may be formed are described here, any material that may serve as a foundation for the electronic devices 160, 170, or any other electronic devices integrating the reconfigurable interconnect 150 as described herein may be used. The substrate 136 may be part of a singulated die (e.g., the dies 2002 of FIG. 5B) or a wafer (e.g., the wafer 2000 of FIG. 5A).

The electronic device 160, 170 may include one or more device layers 138 disposed on the substrate 136. The device layer 138 may include features of one or more transistors 140 (e.g., metal oxide semiconductor field-effect transistors (MOSFETs)) formed on the substrate 136. The device layer 138 may include, for example, one or more source and/or drain (S/D) regions 118, a gate 116 to control current flow in the channel 120 of the transistors 140 between the S/D regions 118, and one or more S/D electrodes 142 (which may take the form of conductive vias) to route electrical signals to/from the S/D regions 118. Adjacent transistors 140 may be isolated from each other by a shallow trench isolation (STI) insulating material 144, in some embodiments. The transistors 140 may include additional features not depicted for the sake of clarity, such as device isolation regions, gate contacts, and the like. The transistors 140 are not limited to the type and configuration depicted in FIGS. 2 and 3 and may include a wide variety of other types and configurations such as, for example, planar transistors, nonplanar transistors, or a combination of both. Nonplanar transistors may include FinFET transistors, such as double-gate transistors or tri-gate transistors, and wrap-around or all-around gate transistors, such as nanoribbon and nanowire transistors.

Each transistor 140 may include a gate 116 including a gate dielectric and a gate electrode. The gate electrode of the transistor 140 may include at least one p-type work function metal or n-type work function metal, depending on whether the transistor 140 is to be a PMOS transistor or an NMOS transistor. For a PMOS transistor, metals that may be used for the gate electrode of the transistor 140 may include, but are not limited to, ruthenium, palladium, platinum, cobalt, nickel, and conductive metal oxides (e.g., ruthenium oxide). For an NMOS transistor, metals that may be used for the gate electrode of the transistor 140 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode of the transistor 140 may include a stack of two or more metal layers, where one or more metal layers are work function metal layers and at least one metal layer is a fill metal layer. Further metal layers may be included for other purposes, such as to act as a barrier layer. Any of the materials discussed herein with reference to the gate electrode of the transistor 140 may be used for the gate electrode 106 of the TFT 100.

The gate dielectric of the transistor 140 may be, for example, silicon oxide, aluminum oxide, or a high-k dielectric, such as hafnium oxide. More generally, the gate dielectric of the transistor 140 may include elements such as hafnium, silicon, oxygen, titanium, tantalum, lanthanum, aluminum, zirconium, barium, strontium, yttrium, lead, scandium, niobium, and zinc. Examples of materials that may be used in the gate dielectric of the transistor 140 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric of the transistor 140 to improve the quality of the gate dielectric of the transistor 140. Any of the materials discussed herein with reference to the gate dielectric of the transistor 140 may be used for the gate dielectric 108 of the TFT 100.

In some embodiments, when viewed as a cross section of the transistor 140 along the source-channel-drain direction, the gate electrode may include, or consist of, a U-shaped structure that includes a bottom portion substantially parallel to the surface of the substrate and two sidewall portions that are substantially perpendicular to the top surface of the substrate. In other embodiments, at least one of the metal layers that form the gate electrode of the transistor 140 may simply be a planar layer that is substantially parallel to the top surface of the substrate and does not include sidewall portions substantially perpendicular to the top surface of the substrate. In other embodiments, the gate electrode of the transistor 140 may include, or consist of, a combination of U-shaped structures and planar non-U-shaped structures. For example, the gate electrode of the transistor 140 may consist of one or more U-shaped metal layers formed atop one or more planar non-U-shaped layers. In some embodiments, the gate electrode may consist of a V-shaped structure.

In some embodiments, a pair of sidewall spacers 146 may be formed on opposing sides of the gate 116 to bracket the gate 116. The sidewall spacers 146 may be formed from a material such as silicon nitride, silicon oxide, silicon carbide, silicon nitride doped with carbon, and silicon oxynitride. Processes for forming sidewall spacers 146 are well known in the art and generally include deposition and etching process steps. In some embodiments, multiple pairs of sidewall spacers 146 may be used; for instance, two pairs, three pairs, or four pairs of sidewall spacers 146 may be formed on opposing sides of the gate stack.

The S/D regions 118 may be formed within the substrate 136 proximate to, e.g. adjacent to, the gate 116 of each transistor 140. For example, the S/D regions 118 may be formed using either an implantation/diffusion process or a deposition process. In the former process, dopants such as boron, aluminum, antimony, phosphorous, or arsenic may be ion-implanted into the substrate 136 to form the S/D regions 118. An annealing process that activates the dopants and causes them to diffuse farther into the substrate 136 may follow the ion-implantation process. In the latter process, an epitaxial deposition process may provide material that is used to fabricate the S/D regions 118. In some implementations, the S/D regions 118 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 118 may be formed using one or more alternate semiconductor materials such as germanium or a group III-V material or alloy. In further embodiments, one or more layers of metal and/or metal alloys may be used to form the S/D regions 118. In some embodiments, an etch process may be performed before the epitaxial deposition to create recesses in the substrate 136 in which the material for the S/D regions 118 is deposited. Any suitable ones of the processes discussed herein with reference to forming the S/D regions 118 of the transistor 140 may be used to form the S/D electrodes 102 and 104 of the TFT 100 in embodiments in which the S/D electrodes 102 and 104 include a doped material.

Electrical signals, such as power and/or input/output (I/O) signals, may be routed to and/or from the transistors 140 of the device layer 138, and/or to and/or from the TFTs 100, through one or more interconnect layers disposed on the device layer 138. FIG. 2 illustrates such one or more interconnect layers disposed on the device layer 138 as the interconnect layer 132 disposed on the device layer 138, the interconnect layer 130 (including the TFT 100) disposed on the interconnect layer 132, and the interconnect layer 134 disposed on the interconnect layer 130. For example, as shown in FIG. 2, electrically conductive features of the device layer 138 (e.g., the S/D regions 118 of the transistors 140) and/or the TFT 100 (e.g., the S/D electrodes 102 and 104) may be electrically coupled with the interconnect structures including conductive vias 112 and/or conductive lines 114 of the interconnect layer 132, while electrically conductive features of the TFT 100 (e.g., the gate electrode 106) may be electrically coupled with the interconnect structures including conductive vias 112 and/or conductive lines 114 of the interconnect layer 134. For the embodiment shown in FIG. 2, the interconnect layer 132 may be referred to as Metal 1 or “M1” layer, the interconnect layer 130 may be referred to as Metal 2 or “M2” layer, while the interconnect layer 134 may be referred to as Metal 3 or “M3” layer. On the other hand, the embodiment shown in FIG. 3 illustrates such one or more interconnect layers disposed on the device layer 138 as the interconnect layer 134 disposed on the device layer 138, the interconnect layer 130 (including the TFT 100) disposed on the interconnect layer 134, and the interconnect layer 132 disposed on the interconnect layer 130. For example, as shown in FIG. 3, electrically conductive features of the device layer 138 (e.g., the gates 116 of the transistors 140) and/or the TFT 100 (e.g., the gate 106) may be electrically coupled with the interconnect structures including conductive vias 112 and/or conductive lines 114 of the interconnect layer 134, while electrically conductive features of the TFT 100 (e.g., the S/D electrode 102, 104) may be electrically coupled with the interconnect structures including conductive vias 112 and/or conductive lines 114 of the interconnect layer 132. For the embodiment shown in FIG. 3, the interconnect layer 134 may be referred to as Metal 1 or “M1” layer, the interconnect layer 130 may be referred to as Metal 2 or “M2” layer, while the interconnect layer 132 may be referred to as Metal 3 or “M3” layer.

As the foregoing description illustrates, in various electronic devices where the reconfigurable interconnect arrangement 150 with one or more TFTs 100 may be implemented, the one or more TFTs 100 may be implemented in a different layer with respect to the substrate 136 than other circuit components, e.g. than the front-end transistor(s) 140. Moreover, within a layer where a TFT 100 is implemented, the S/D electrodes 102, 104 of the TFT 100 may be implemented in a first sub-layer, the channel material 110 may be implemented in a second sub-layer, while the gate stack with the gate dielectric 108 and the gate electrode 106 may be implemented in a third sub-layer, where the second sub-layer is between the first sub-layer and the third sub-layer. In some embodiments (e.g. that shown in FIG. 2), such a first sub-layer (i.e. the S/D electrodes 102, 104) may be between the second sub-layer (i.e. the channel material 110) and the layer in which one or more front-end transistors 140 are implemented. In other embodiments (e.g. that shown in FIG. 3), such a third sub-layer (i.e. the gate electrode 106) may be between the second sub-layer (i.e. the channel material 110) and the layer in which one or more front-end transistors 140 are implemented.

The one or more interconnect layers 130, 132, and 134 may form an ILD stack of the electronic devices 160, 170. The TFT 100 may itself be included in the ILD stack as a “back-end” device. In some embodiments, an array of TFTs 100 may take the place of conductive vias and lines in a portion of the ILD stack, enabling the interconnects of the ILD stack to be reconfigured in various ways. In some embodiments, an array of TFTs 100 may share “layers” in an ILD stack with conductive vias and/or lines (e.g., an array of TFTs 100 may be arranged laterally with conductive vias and/or lines in the ILD stack).

As noted above, the electronic devices 160, 170 include the TFT 100, which may be electrically coupled to one or more of the transistor 140s. In both FIGS. 2 and 3, the TFT 100 is illustrated as being included in the second interconnect layer, M2, 130, but the TFT 100 may be located in any suitable interconnect layer or other portion of the electronic devices 160, 170.

The interconnect structures may be arranged within the interconnect layers provided over the device layer 138 to route electrical signals according to a wide variety of designs (in particular, the arrangement is not limited to the particular configuration of interconnect structures depicted in FIGS. 2 and 3). Although a particular number of interconnect layers is depicted in FIGS. 2 and 3, embodiments of the present disclosure include electronic devices having more or fewer interconnect layers than depicted.

In some embodiments, various interconnect structures described herein may include conductive lines 114 (sometimes referred to as “trench structures”) and/or conductive vias 112 (sometimes referred to as “holes”) filled with an electrically conductive material such as a metal. The conductive lines 114 may be arranged to route electrical signals in a direction of a plane that is substantially parallel with a surface of the substrate 136 upon which the device layer 138 and the reconfigurable interconnect arrangement 150 are formed. For example, the conductive lines 114 may route electrical signals in a direction in and out of the page from the perspective of FIGS. 1-3. The conductive vias 112 may be arranged to route electrical signals in a direction of a plane that is substantially perpendicular to the surface of the substrate 136 upon which the device layer 138 and the reconfigurable interconnect arrangement 150 are formed. In some embodiments, the conductive vias 112 may electrically couple conductive lines 114 of different interconnect layers together.

Although the conductive lines 114 and the conductive vias 112 are structurally delineated with a line within each interconnect layer shown in the FIGS. for the sake of clarity, the conductive lines 114 and the conductive vias 112 may be structurally and/or materially contiguous (e.g., simultaneously filled during a dual-damascene process) in some embodiments. Additional interconnect layers may be formed in succession on the M3 interconnect layers (i.e. layer 134 for the embodiment of FIG. 2 or layer 132 for the embodiment of FIG. 3) according to known techniques and configurations.

As also shown in FIGS. 2 and 3, the electronic devices 160, 170 may include a solder resist material 148 (e.g., polyimide or similar material) and one or more bond pads 156 formed on the interconnect layers. The bond pads 156 may be electrically coupled with the interconnect structures and may route the electrical signals of the electronic devices 160, 170, including electrical signals of the reconfigurable interconnect arrangement 150, to other external devices. For example, solder bonds may be formed on the one or more bond pads 156 to mechanically and/or electrically couple a chip including the electronic devices 160, 170, and the reconfigurable interconnect arrangement 150 with another component (e.g., a circuit board). In other embodiments, the electronic devices including the reconfigurable interconnect arrangement 150 may include other structures to route the electrical signals from the interconnect layers than depicted in FIGS. 2 and 3. For example, the bond pads 156 may be replaced by or may further include other analogous features (e.g., posts) that route electrical signals to external components.

The electronic devices 160 and 170 illustrated in FIGS. 2 and 3 do not represent an exhaustive set of electronic devices in which reconfigurable interconnect arrangements 150 with one or more TFTs 100 may be included, but that may provide examples of such devices/structures. For example, in other embodiments, any of the reconfigurable interconnect arrangements 150 with one or more TFTs 100 described herein may be used to interconnect transistors implementing tri-gate or all-around gate architectures, or may be used to interconnect circuit elements other than transistors, e.g. storage elements. FIGS. 2 and 3 are intended to show relative arrangements of the components therein, and, in various further embodiments, the electronic devices 160 and 170 may include other components that are not illustrated (e.g., conductive pathways to the source, drain, and gate electrodes of the transistors 140, etc.).

The reconfigurable interconnect arrangements 150 with one or more TFTs 100 and various electronic devices including such arrangements as described herein may be formed using any suitable techniques. Some of such technique may include suitable deposition and patterning techniques. As used herein, “patterning” may refer to forming a pattern in one or more materials using any suitable techniques (e.g., applying a resist, patterning the resist using lithography, and then etching the one or more material using dry etching, wet etching, or any appropriate technique).

For example, various interconnect structures including one or more conductive pathways described herein, e.g. the conductive pathways 122, 124, 126, or other conductive pathways including one or more conductive lines 114 and/or conductive vias 112, may be provided using any suitable fabrication techniques, e.g., subtractive, additive, damascene, dual-damascene, etc.

Additionally, as noted above, the interconnect structures shown in FIGS. 1-3 are simply illustrative, and subsequent operations may be performed on any suitable “starting” assembly. For example, in some embodiments, a storage element or various front-end transistors may be included in the reconfigurable interconnect arrangements 150 with one or more TFTs 100 and various electronic devices including such arrangements, and may be electrically coupled to at least some of the electrodes during fabrication of the TFT 100.

The techniques used to provide the material for various S/D electrodes described herein, e.g. the S/D electrodes 102 and 104, may depend on the particular materials, and may include atomic layer deposition (ALD), physical vapor deposition (PVD), or chemical vapor deposition (CVD). In embodiments in which the electrodes, e.g. the S/D electrodes 102 and 104, include a dopant, a material may be initially deposited and then doped with the dopant using any suitable technique. Any suitable technique may be used to deposit the material for the gate electrodes described herein, e.g. the gate electrode 106, such as sputtering, evaporation, ALD, or CVD techniques.

Any suitable technique may be used to provide the insulating materials described herein, e.g. the insulating material 128 or the STI insulating material 144, such as spin coating, CVD, or plasma-enhanced CVD (PECVD). In some embodiments, the gate dielectrics described herein, e.g. the gate dielectric 108, may be deposited using ALD.

As noted above, in some embodiments, the material for the channel 110 of the TFT 100 may be deposited using a thin film deposition technique (e.g., sputtering, evaporation, molecular beam epitaxy (MBE), CVD, or ALD).

In some embodiments, fabrication of the reconfigurable interconnect arrangements 150 with one or more TFTs 100 and various electronic devices including such arrangements may include providing a layer of a mask material and patterning the mask material. For example, a portion of the material for the S/D electrodes 102, 104 may be exposed by the patterning of the mask material, and the pattern in the mask material may correspond to a desired pattern for the S/D electrodes 102 and 104, as known in the art. In some embodiments, the mask material may be a photoresist that may be removed in subsequent operations. In some embodiments, the mask material may be a hardmask that may be removed or may remain as part of the electronic devices 160, 170 (not shown in the drawings for clarity of illustration), or any other electronic devices that may include the reconfigurable interconnect arrangements 150 with one or more TFTs 100 as described herein.

As noted above, in some embodiments, an electronic device with the reconfigurable interconnect arrangement 150 may include multiple TFTs 100. Some of these TFTs 100 may be fabricated simultaneously, and may be electrically coupled in any of a number of ways, all of which being within the scope of the present disclosure.

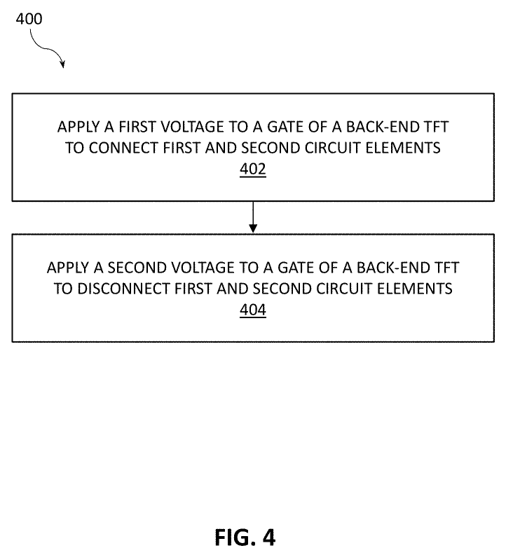

FIG. 4 is a flow diagram of an illustrative method 400 of operating an electronic device using a reconfigurable interconnect arrangement with at least one TFT, e.g. the reconfigurable interconnect arrangement 150 with the TFT 100, according to some embodiments of the present disclosure. Although the operations discussed below with reference to the method 400 (and the other methods disclosed herein) are illustrated in a particular order and depicted once each, these operations may be repeated or performed in a different order (e.g., in parallel), as suitable. Additionally, various operations may be omitted, as suitable. Various operations of the method 400 (and the other methods disclosed herein) may be illustrated with reference to one or more of the embodiments discussed above, but the method 400 may be used to operate any suitable electronic device (including any suitable ones of the embodiments disclosed herein).

The method 400 may include a process 402 in which a first voltage may be applied to the gate electrode 106 of the TFT 100 to connect first and second circuit elements connected to, respectively, the S/D electrodes 102 and 104, and a process 404 in which a second voltage, different from the first voltage, may be applied to the gate electrode 106 of the TFT 100 to disconnect first and second circuit elements. In some embodiments, any of the first and second circuit elements may be the front-end transistors 140 or storage elements as described herein. Application of suitable voltages to the gate electrode 106 of the TFT 100 may control the flow of current to or through the first or/and second circuit elements. In other words, the TFT 100 may be configured to connect a given circuit element, e.g. a storage element or a front-end transistor, or disconnect such a circuit element from, other circuitry, e.g. another storage element or/and another front-end transistor, depending on a voltage applied to the gate electrode of the TFT 100.

Reconfigurable interconnect arrangements with one or more TFTs as disclosed herein may be included in any suitable electronic device. FIGS. 5-8 illustrate various examples of apparatuses that may include one or more of the reconfigurable interconnect arrangements with one or more TFTs in each as disclosed herein.

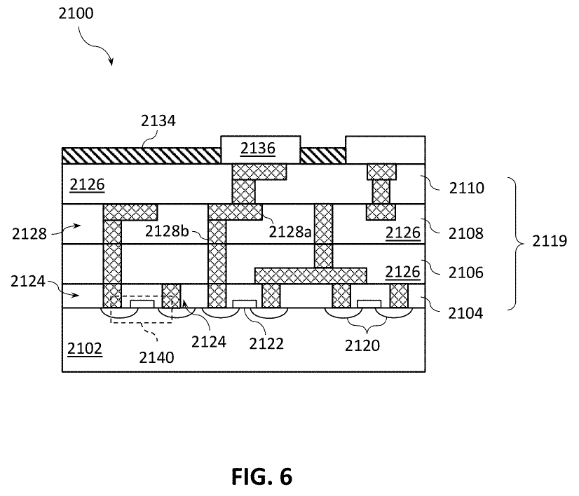

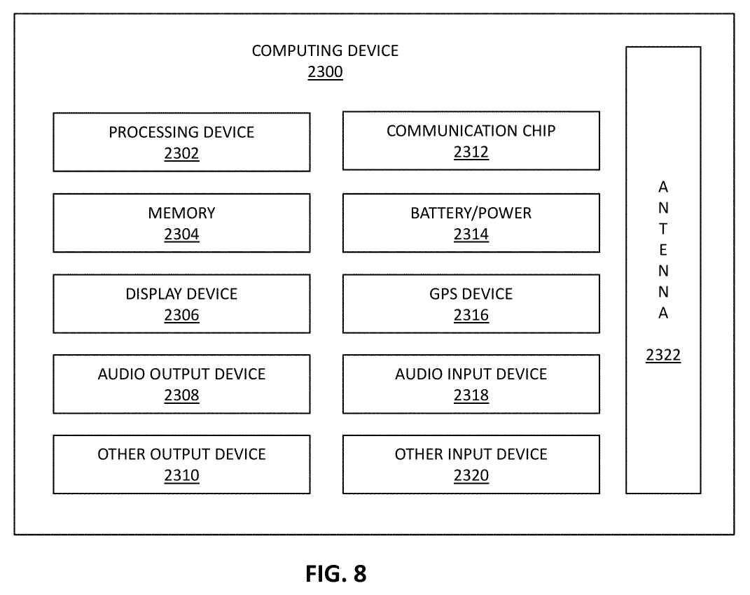

FIGS. 5A-5B are top views of a wafer 2000 and dies 2002 that may include one or more reconfigurable interconnect arrangements with one or more TFTs in each in accordance with any of the embodiments disclosed herein. The wafer 2000 may be composed of semiconductor material and may include one or more dies 2002 having IC structures formed on a surface of the wafer 2000. Each of the dies 2002 may be a repeating unit of a semiconductor product that includes any suitable IC, e.g. ICs which may include one or more reconfigurable interconnect arrangements 150, each of which including one or more TFTs 100, or/and one or more electronic devices 160 or/and 170, or any other device components implementing reconfigurable interconnect arrangements with one or more TFTs as described herein. After the fabrication of the semiconductor product is complete (e.g., after manufacture of one or more reconfigurable interconnect arrangements 150, or/and one or more electronic devices 160 or/and 170 as described herein), the wafer 2000 may undergo a singulation process in which each of the dies 2002 is separated from one another to provide discrete “chips” of the semiconductor product. In particular, devices that include one or more reconfigurable interconnect arrangements 150 as disclosed herein may take the form of the wafer 2000 (e.g., not singulated) or the form of the die 2002 (e.g., singulated). The die 2002 may include one or more transistors (e.g., one or more of the transistors 2140 of FIG. 6, discussed below, which may take the form of any of the front-end transistors 140 as described herein), one or more reconfigurable interconnect arrangements with one or more back-end TFTs as described herein, and/or supporting circuitry to route electrical signals to any of the transistors, as well as any other IC components. In some embodiments, the wafer 2000 or the die 2002 may include a memory device (e.g., a static random access memory (SRAM) device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2302 of FIG. 8) or other logic that is configured to store information in the memory devices or execute instructions stored in the memory array.

FIG. 6 is a cross-sectional side view of an IC device 2100 that may include one or more reconfigurable interconnect arrangements with one or more TFTs in each in accordance with any of the embodiments disclosed herein. The IC device 2100 may be formed on a substrate 2102 (e.g., the wafer 2000 of FIG. 5A) and may be included in a die (e.g., the die 2002 of FIG. 5B). The substrate 2102 may be the semiconductor substrate 136 as described above. The substrate 2102 may be part of a singulated die (e.g., the dies 2002 of FIG. 5B) or a wafer (e.g., the wafer 2000 of FIG. 5A).

The IC device 2100 may include one or more device layers 2104 disposed on the substrate 2102. The device layer 2104 may include features of one or more transistors 2140 (e.g., MOSFETs) formed on the substrate 2102. The device layer 2104 may include, for example, one or more source and/or drain (S/D) regions 2120, a gate 2122 to control current flow in the transistors 2140 between the S/D regions 2120, and one or more S/D contacts 2124 to route electrical signals to/from the S/D regions 2120. The S/D regions 2120 may be formed within the substrate 2102 either adjacent to or at a distance from the gate 2122 of each transistor 2140, using any suitable processes known in the art, some of which are described above. The transistors 2140 may include additional features not depicted for the sake of clarity, such as additional device isolation regions, gate contacts, and the like. The transistors 2140 are not limited to the type and configuration depicted in FIG. 6 and may include a wide variety of other types and configurations such as, for example, planar transistors, nonplanar transistors, or a combination of both. In some embodiments, the transistors 2140 may be the front-end transistors 140 described herein.

Each transistor 2140 may include a gate 2122 formed of at least two layers, a gate dielectric layer and a gate electrode layer. The descriptions provided above with respect to the gate dielectric 116 and the gate electrode 106 are generally applicable to the gate dielectric layer and the gate electrode layer, respectively, of a transistor 2140 and, therefore, in the interests of brevity, are not repeated here.

Electrical signals, such as power and/or input/output (I/O) signals, may be routed to and/or from the transistors 2140 of the device layer 2104 through one or more interconnect layers disposed on the device layer 2104 (illustrated in FIG. 6 as interconnect layers 2106-2110). For example, electrically conductive features of the device layer 2104 (e.g., the gate 2122 and the S/D contacts 2124) may be electrically coupled with the interconnect structures 2128 of the interconnect layers 2106-2110. The one or more interconnect layers 2106-2110 may form an ILD stack 2119 of the IC device 2100. Although not specifically shown in FIG. 6, the ILD stack 2119 of the IC device 2100 may include one or more reconfigurable interconnect arrangements with one or more TFTs in each in accordance with any of the embodiments disclosed herein.

The interconnect structures 2128 may be arranged within the interconnect layers 2106-2110 to route electrical signals according to a wide variety of designs (in particular, the arrangement is not limited to the particular configuration of interconnect structures 2128 depicted in FIG. 6). Although a particular number of interconnect layers 2106-2210 is depicted in FIG. 6, embodiments of the present disclosure include IC devices having more or fewer interconnect layers than depicted.

In some embodiments, the interconnect structures 2128 may include trench structures 2128a (sometimes referred to as “lines”) and/or via structures 2128b (sometimes referred to as “holes”) filled or lined with an electrically conductive material such as a metal. Similar to the conductive lines 114 described herein, the trench structures 2128a may be arranged to route electrical signals in a direction of a plane that is substantially parallel with a surface of the substrate 2102 upon which the device layer 2104 is formed. For example, the trench structures 2128a may route electrical signals in a direction in and out of the page from the perspective of FIG. 6. Similar to the conductive vias 112 described herein, the via structures 2128b may be arranged to route electrical signals in a direction of a plane that is substantially perpendicular to the surface of the substrate 2102 upon which the device layer 2104 is formed. In some embodiments, the via structures 2128b may electrically couple trench structures 2128a of different interconnect layers 2106-2110 together.

The interconnect layers 2106-2110 may include a dielectric material 2126 disposed between the interconnect structures 2128, as shown in FIG. 6. In some embodiments, the dielectric material 2126 disposed between the interconnect structures 2128 in different ones of the interconnect layers 2106-2110 may have different compositions; in other embodiments, the composition of the dielectric material 2126 between different interconnect layers 2106-2110 may be the same. In some embodiments, the dielectric material 2126 may be the insulating material 128 described herein.

A first interconnect layer 2106 (referred to as Metal 1 or “M1”) may be formed directly on the device layer 2104. In some embodiments, the first interconnect layer 2106 may include trench structures 2128a and/or via structures 2128b, as shown. The trench structures 2128a of the first interconnect layer 2106 may be coupled with contacts (e.g., the S/D contacts 2124) of the device layer 2104.

A second interconnect layer 2108 (referred to as Metal 2 or “M2”) may be formed directly on the first interconnect layer 2106. In some embodiments, the second interconnect layer 2108 may include via structures 2128b to couple the trench structures 2128a of the second interconnect layer 2108 with the trench structures 2128a of the first interconnect layer 2106. Although the trench structures 2128a and the via structures 2128b are structurally delineated with a line within each interconnect layer (e.g., within the second interconnect layer 2108) for the sake of clarity, the trench structures 2128a and the via structures 2128b may be structurally and/or materially contiguous (e.g., simultaneously filled during a dual-damascene process) in some embodiments.

A third interconnect layer 2110 (referred to as Metal 3 or “M3”) (and additional interconnect layers, as desired) may be formed in succession on the second interconnect layer 2108 according to similar techniques and configurations described in connection with the second interconnect layer 2108 or the first interconnect layer 2106.

The IC device 2100 may include a solder resist material 2134 (e.g., polyimide or similar material) and one or more bond pads 2136 formed on the interconnect layers 2106-2110. The bond pads 2136 may be electrically coupled with the interconnect structures 2128 and configured to route the electrical signals of the transistor(s) 2140 to other external devices. For example, solder bonds may be formed on the one or more bond pads 2136 to mechanically and/or electrically couple a chip including the IC device 2100 with another component (e.g., a circuit board). The IC device 2100 may have other alternative configurations to route the electrical signals from the interconnect layers 2106-2110 than depicted in other embodiments. For example, the bond pads 2136 may be replaced by or may further include other analogous features (e.g., posts) that route the electrical signals to external components.

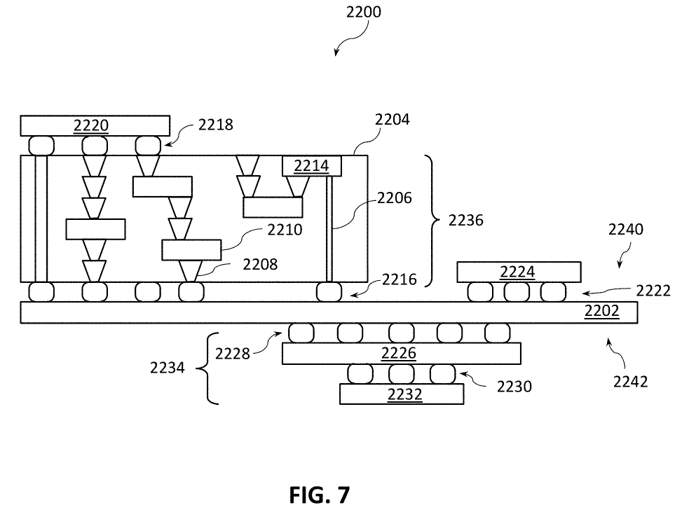

FIG. 7 is a cross-sectional side view of an IC device assembly 2200 that may include one or more reconfigurable interconnect arrangements with one or more TFTs in each in accordance with any of the embodiments disclosed herein. The IC device assembly 2200 includes a number of components disposed on a circuit board 2202 (which may be, e.g., a motherboard). The IC device assembly 2200 includes components disposed on a first face 2240 of the circuit board 2202 and an opposing second face 2242 of the circuit board 2202; generally, components may be disposed on one or both faces 2240 and 2242. In particular, any suitable ones of the components of the IC device assembly 2200 may include any of the dies with reconfigurable interconnect arrangements with one or more TFTs in each in accordance with any of the embodiments disclosed herein, e.g. may include any of the reconfigurable interconnect arrangements 150 with one or more TFTs 100 illustrated in FIGS. 1-3, or any electronic devices including such reconfigurable interconnect arrangements, e.g. any of the electronic devices 160 and 170 illustrated in FIGS. 2-3, or any further embodiments of such electronic devices and reconfigurable interconnect arrangements described herein. The IC device assembly 2200 may include any of the reconfigurable interconnect arrangements with one or more TFTs, or electronic devices incorporating such reconfigurable interconnect arrangements, implemented in one or more packages. A “package” may refer to an electronic component that includes one or more IC devices that are structured for coupling to other components; for example, a package may include a die coupled to a package substrate that provides electrical routing and mechanical stability to the die.

In some embodiments, the circuit board 2202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2202. In other embodiments, the circuit board 2202 may be a non-PCB substrate.

The IC device assembly 2200 illustrated in FIG. 7 may include a package-on-interposer structure 2236 coupled to the first face 2240 of the circuit board 2202 by coupling components 2216. The coupling components 2216 may electrically and mechanically couple the package-on-interposer structure 2236 to the circuit board 2202, and may include solder balls (as shown in FIG. 7), male and female portions of a socket, an adhesive, an underfill material, and/or any other suitable electrical and/or mechanical coupling structure.

The package-on-interposer structure 2236 may include an IC package 2220 coupled to an interposer 2204 by coupling components 2218. The coupling components 2218 may take any suitable form for the application, such as the forms discussed above with reference to the coupling components 2216. Although a single IC package 2220 is shown in FIG. 7, multiple IC packages may be coupled to the interposer 2204; indeed, additional interposers may be coupled to the interposer 2204. The interposer 2204 may provide an intervening substrate used to bridge the circuit board 2202 and the IC package 2220. The IC package 2220 may be or include, for example, a die (the die 2002 of FIG. 5B), an IC device (e.g., the IC device 2100 of FIG. 6), or any other suitable component, and may include any embodiments of one or more reconfigurable interconnect arrangements with one or more TFTs in each as described herein or any of the electronic devices including such arrangements, e.g. as illustrated in FIGS. 2-3, or any further embodiments of such reconfigurable interconnect arrangements and electronic devices described herein. Generally, the interposer 2204 may spread a connection to a wider pitch or reroute a connection to a different connection. For example, the interposer 2204 may couple the IC package 2220 (e.g., a die) to a ball grid array (BGA) of the coupling components 2216 for coupling to the circuit board 2202. In the embodiment illustrated in FIG. 7, the IC package 2220 and the circuit board 2202 are attached to opposing sides of the interposer 2204; in other embodiments, the IC package 2220 and the circuit board 2202 may be attached to a same side of the interposer 2204. In some embodiments, three or more components may be interconnected by way of the interposer 2204.

The interposer 2204 may be formed of an epoxy resin, a fiberglass-reinforced epoxy resin, a ceramic material, or a polymer material such as polyimide. In some implementations, the interposer 2204 may be formed of alternate rigid or flexible materials that may include the same materials described above for use in a semiconductor substrate, such as silicon, germanium, and other group III-N and group IV materials. The interposer 2204 may include metal interconnects 2208 and vias 2210, including but not limited to through-silicon vias (TSVs) 2206. The interposer 2204 may further include embedded devices 2214, including both passive and active devices. Such devices may include, but are not limited to, reconfigurable interconnect arrangements 150 with one or more TFTs 100, as well as any capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 2204. The package-on-interposer structure 2236 may take the form of any of the package-on-interposer structures known in the art.

The IC device assembly 2200 may include an IC package 2224 coupled to the first face 2240 of the circuit board 2202 by coupling components 2222. The coupling components 2222 may take the form of any of the embodiments discussed above with reference to the coupling components 2216, and the IC package 2224 may take the form of any of the embodiments discussed above with reference to the IC package 2220.

As also shown in FIG. 7, the IC device assembly 2200 may further include a package-on-package structure 2234 coupled to the second face 2242 of the circuit board 2202 by coupling components 2228. The package-on-package structure 2234 may include an IC package 2226 and an IC package 2232 coupled together by coupling components 2230 such that the IC package 2226 is disposed between the circuit board 2202 and the IC package 2232. The coupling components 2228 and 2230 may take the form of any of the embodiments of the coupling components 2216 discussed above, and the IC packages 2226 and 2232 may take the form of any of the embodiments of the IC package 2220 discussed above and may include any of the reconfigurable interconnect arrangements 150 with one or more TFTs 100 as described herein. The package-on-package structure 2234 may be configured in accordance with any of the package-on-package structures known in the art.

FIG. 8 is a block diagram of an example computing device 2300 that may include one or more device assemblies implementing any number of reconfigurable interconnect arrangements with one or more TFTs in each in accordance with any of the embodiments disclosed herein. For example, any suitable ones of the components of the computing device 2300 may include a die (e.g., the die 2002 (FIG. 5B)) having reconfigurable interconnect arrangements with one or more TFTs as described herein, e.g. any embodiments of one or more reconfigurable interconnect arrangements 150, each of which including one or more TFTs 100, or/and one or more electronic devices 160 or/and 170, or any other device components implementing reconfigurable interconnect arrangements with one or more TFTs as described herein. Any one or more of the components of the computing device 2300 may include, or be included in, an IC device 2100 (FIG. 6). Any one or more of the components of the computing device 2300 may include, or be included in, an IC device assembly 2200 (FIG. 7).

A number of components are illustrated in FIG. 8 as included in the computing device 2300, but any one or more of these components may be omitted or duplicated, as suitable for the application. In some embodiments, some or all of the components included in the computing device 2300 may be attached to one or more motherboards. In some embodiments, some or all of these components are fabricated onto a single system-on-chip (SoC) die.

Additionally, in various embodiments, the computing device 2300 may not include one or more of the components illustrated in FIG. 8, but the computing device 2300 may include interface circuitry for coupling to the one or more components. For example, the computing device 2300 may not include a display device 2306, but may include display device interface circuitry (e.g., a connector and driver circuitry) to which a display device 2306 may be coupled. In another set of examples, the computing device 2300 may not include an audio input device 2318 or an audio output device 2308, but may include audio input or output device interface circuitry (e.g., connectors and supporting circuitry) to which an audio input device 2318 or audio output device 2308 may be coupled.

The computing device 2300 may include a processing device 2302 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2302 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2300 may include a memory 2304, which may itself include one or more memory devices such as volatile memory (e.g., DRAM), nonvolatile memory (e.g., read-only memory (ROM)), flash memory, solid-state memory, and/or a hard drive. In some embodiments, the memory 2304 may include memory that shares a die with the processing device 2302. This memory may be used as cache memory and may include embedded DRAM (eDRAM) or spin transfer torque MRAM (STT-M RAM). In some embodiments, any of the processing device 2302 and the memory 2304 may include one or more reconfigurable interconnect arrangements 150 with one or more TFTs 100 as described herein, or any of the electronic devices implementing such reconfigurable interconnect arrangements as described herein.

In some embodiments, the computing device 2300 may include a communication chip 2312 (e.g., one or more communication chips). For example, the communication chip 2312 may be configured for managing wireless communications for the transfer of data to and from the computing device 2300. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2312 may operate in accordance with other wireless protocols in other embodiments. The computing device 2300 may include an antenna 2322 to facilitate wireless communications and/or to receive other wireless communications (such as AM or FM radio transmissions).

In some embodiments, the communication chip 2312 may manage wired communications, such as electrical, optical, or any other suitable communication protocols (e.g., the Ethernet). As noted above, the communication chip 2312 may include multiple communication chips. For instance, a first communication chip 2312 may be dedicated to shorter-range wireless communications such as Wi-Fi or Bluetooth, and a second communication chip 2312 may be dedicated to longer-range wireless communications such as global positioning system (GPS), EDGE, GPRS, CDMA, WiMAX, LTE, EV-DO, or others. In some embodiments, a first communication chip 2312 may be dedicated to wireless communications, and a second communication chip 2312 may be dedicated to wired communications.

The computing device 2300 may include battery/power circuitry 2314. The battery/power circuitry 2314 may include one or more energy storage devices (e.g., batteries or capacitors) and/or circuitry for coupling components of the computing device 2300 to an energy source separate from the computing device 2300 (e.g., AC line power).

The computing device 2300 may include a display device 2306 (or corresponding interface circuitry, as discussed above). The display device 2306 may include any visual indicators, such as a heads-up display, a computer monitor, a projector, a touchscreen display, a liquid crystal display (LCD), a light-emitting diode display, or a flat panel display, for example.

The computing device 2300 may include an audio output device 2308 (or corresponding interface circuitry, as discussed above). The audio output device 2308 may include any device that generates an audible indicator, such as speakers, headsets, or earbuds, for example.

The computing device 2300 may include an audio input device 2318 (or corresponding interface circuitry, as discussed above). The audio input device 2318 may include any device that generates a signal representative of a sound, such as microphones, microphone arrays, or digital instruments (e.g., instruments having a musical instrument digital interface (MIDI) output).

The computing device 2300 may include a GPS device 2316 (or corresponding interface circuitry, as discussed above). The GPS device 2316 may be in communication with a satellite-based system and may receive a location of the computing device 2300, as known in the art.

The computing device 2300 may include an other output device 2310 (or corresponding interface circuitry, as discussed above). Examples of the other output device 2310 may include an audio codec, a video codec, a printer, a wired or wireless transmitter for providing information to other devices, or an additional storage device.

The computing device 2300 may include an other input device 2320 (or corresponding interface circuitry, as discussed above). Examples of the other input device 2320 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2300 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2300 may be any other electronic device that processes data.

### Select Examples

The following paragraphs provide examples of various ones of the embodiments disclosed herein.

Example 1 provides a device that includes a semiconductor substrate, a first transistor (e.g. a front-end transistor 140) in a first layer over the semiconductor substrate, and a second transistor (e.g. a back-end transistor 110) in a second layer over the semiconductor substrate, the second layer different from the first layer, where the second transistor is a thin-film transistor (and, thus, the channel of the second transistor includes a thin film material).

Example 2 provides the device according to Example 1, where the second transistor includes a first source/drain (S/D) electrode, a second S/D electrode, a channel material, a gate electrode, and a gate dielectric between the gate electrode and the channel material.

Example 3 provides the device according to Example 2, where the first S/D electrode and the second S/D electrode of the second transistor are in a first sub-layer of the second layer, the channel material of the second transistor is in a second sub-layer of the second layer, and the gate electrode of the second transistor is in a third sub-layer of the second layer, and the second sub-layer is between the first sub-layer and the third sub-layer.

Example 4 provides the device according to Example 3, where the first sub-layer is between the second sub-layer and the first layer.

Example 5 provides the device according to Example 3, where the third sub-layer is between the second sub-layer and the first layer.

Example 6 provides the device according to any one of Examples 2-4, where the first transistor includes a first S/D electrode, a second S/D electrode, a channel material, a gate electrode, and a gate dielectric between the gate electrode and the channel material of the first transistor, and the first S/D electrode of the second transistor is electrically continuous (i.e. is electrically connected to) with the first S/D electrode of the first transistor.

Example 7 provides the device according to Example 6, where the device further includes a third transistor in the first layer, the third transistor including a first S/D electrode, a second S/D electrode, a channel material, a gate electrode, and a gate dielectric between the gate electrode and the channel material of the third transistor, and the second S/D electrode of the second transistor is electrically continuous with the first S/D electrode of the third transistor.

Example 8 provides the device according to any one of Examples 2, 3, or 5, where the first transistor includes a first S/D electrode, a second S/D electrode, a channel material, a gate electrode, and a gate dielectric between the gate electrode and the channel material of the first transistor, and the gate electrode of the second transistor is electrically continuous with the gate electrode of the first transistor.

Example 9 provides the device according to any one of Examples 2-8, where the channel material of the second transistor is between one of the first S/D electrode and the second S/D electrode of the second transistor and the gate electrode of the second transistor.

Example 10 provides the device according to Example 9, where each of the first S/D electrode, the second S/D electrode, and the gate electrode of the second transistor are electrically connected to at least one of a respective conductive via and a respective conductive line.

Example 11 provides the device according to any one of Examples 2-10, where the first S/D electrode or the second S/D electrode of the second transistor includes a metal.

Example 12 provides the device according to any one of Examples 2-10, where the first S/D electrode or the second S/D electrode of the second transistor includes a semiconductor and an n-type dopant.

Example 13 provides the device according to any one of Examples 2-12, where the channel material of the second transistor includes one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, and black phosphorus.

Example 14 provides the device according to any one of Examples 2-13, further including a storage element coupled to the first S/D electrode or the second S/D electrode of the second transistor.

Example 15 provides the device according to Example 14, where the storage element includes a resistive random access memory (RRAM) element, a dynamic random access memory (DRAM) element, or a magnetic random access memory (MRAM) element.

Example 16 provides a device that includes a semiconductor substrate, a thin-film transistor in a layer over the semiconductor substrate, the thin-film transistor being a bottom-gate transistor, one or more metal interconnect layers above the layer of the thin-film transistor, and one or more metal interconnect layers below the layer of the thin-film transistor (e.g. between the layer of the thin-film transistor and the semiconductor substrate).

Example 17 provides the device according to Example 16, where the thin-film transistor includes a first source/drain (S/D) electrode, a second S/D electrode, a channel material, a gate electrode, and a gate dielectric between the gate electrode and the channel material, and where each of the first S/D electrode, the second S/D electrode, and the gate electrode of the thin-film transistor are electrically connected to at least one of a conductive via and a conductive line.

Example 18 provides the device according to Example 16, where the thin-film transistor includes a first source/drain (S/D) electrode, a second S/D electrode, a channel material, a gate electrode, and a gate dielectric between the gate electrode and the channel material, and where the device further includes a storage element coupled to the first S/D electrode or the second S/D electrode of the thin-film transistor.

Example 19 provides the device according to Example 18, where the storage element includes a resistive random access memory (RRAM) element, a dynamic random access memory (DRAM) element, or a magnetic random access memory (MRAM) element.

Example 20 provides the device according to Examples 18 or 19, further including other circuitry, where the thin-film transistor is configured to connect the storage element to, or disconnect the storage element from, the other circuitry depending on a voltage applied to the gate electrode of the thin-film transistor.

Example 21 provides the device according to Example 16, where the thin-film transistor includes first source/drain (S/D) electrode, a second S/D electrode, a channel material, a gate electrode, and a gate dielectric between the gate electrode and the channel material, and where the device further includes an other transistor coupled to the first S/D electrode or the second S/D electrode of the thin-film transistor.

Example 22 provides the device according to Example 21, further including other circuitry, where the thin-film transistor is configured to connect the other transistor to, or disconnect the other transistor from, the other circuitry depending on a voltage applied to the gate electrode of the thin-film transistor.

Example 23 provides the device according to any one of Examples 16-22, where the thin-film transistor includes a channel material including one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, and black phosphorus.

Example 24 provides a method of operating an electronic device, the method including applying a first voltage to a gate electrode of a thin-film transistor to connect a first circuit element to a second circuit element, and applying a second voltage to the gate electrode of the thin-film transistor to disconnect the first circuit element from the second circuit element, where the thin-film transistor is over a semiconductor substrate, and the electronic device includes at least one metal interconnect layer between the thin-film transistor and a semiconductor substrate. The electronic device may, optionally, further include at least one metal interconnect layer above the thin-film transistor.

Example 25 provides the method according to Example 24, where the thin-film transistor, the first circuit element, the second circuit element, and the at least one interconnect layer are included in a single die.

In some embodiments, the electronic device of any one of claims 24-25 may be the device according to any one of claims 1-15 where the thin-film transistor of the method of any one of claims 24-25 is the second transistor of the device of any one of claims 1-15.

In some embodiments, the electronic device of any one of claims 24-25 may be the device according to any one of claims 16-23 where the thin-film transistor of the method of any one of claims 24-25 is the thin-film transistor of the device of any one of claims 16-23.

Example 26 provides an integrated circuit (IC) assembly that includes a die and a further IC element. The die may include a thin-film transistor in a first layer of the die, one or more metal interconnect layers above the first layer, one or more metal interconnect layers below the first layer, and conductive contacts at a first face of the die, where the conductive contacts at the first face of the die are electrically coupled to conductive contacts of the further IC element.

Example 27 provides the IC assembly according to Example 26, where the die includes a reconfigurable interconnect arrangement.

Example 28 provides the IC assembly according to Examples 26 or 27, where the thin-film transistor is a bottom-gate transistor.

Example 29 provides the IC assembly according to any one of Examples 26-28, where the further IC element is one of an interposer, a circuit board, a flexible board, or a package substrate.

In some embodiments, the die of the IC assembly of any one of claims 26-29 may be the device according to any one of claims 1-15 where the thin-film transistor of the IC assembly of any one of claims 26-29 is the second transistor of the device of any one of claims 1-15.

In some embodiments, the die of the IC assembly of any one of claims 26-29 may be the device according to any one of claims 16-23 where the thin-film transistor of the IC assembly of any one of claims 26-29 is the thin-film transistor of the device of any one of claims 16-23.

Example 30 provides a computing device that includes a package substrate, and an integrated circuit (IC) die coupled to the package substrate, where the IC die includes a thin-film transistor in a first layer of the die, one or more metal interconnect layers above the first layer, and one or more metal interconnect layers below the first layer.

Example 31 provides the computing device according to Example 30, where the computing device is a wearable computing device or a handheld computing device.

Example 32 provides the computing device according to Examples 30 or 31, where the computing device further includes one or more communication chips and an antenna.

Example 33 provides the computing device according to any one of Examples 30-33, where the package substrate and the IC die are part of an IC package, and the computing device further includes a motherboard coupled to the IC package.

In some further claims, the IC die of the computing device according to any one of claims 30-33 may include the device according to any one of claims 1-15 so that the second transistor of the device according to any one of claims 1-15 is the thin-film transistor of the IC die of the computing device according to any one of claims 30-33.

In some further claims, the IC die of the computing device according to any one of claims 30-33 may include the device according to any one of claims 16-23 so that the thin-film transistor of the device according to any one of claims 16-23 is the thin-film transistor of the IC die of the computing device according to any one of claims 30-33.

In some further claims, the IC die of the computing device according to any one of claims 30-33 may be an electronic device operated according to the method of any one of claims 24-25.

Still further claims may provide the computing device according to any one of claims 30-33, wherein the IC die and the package substrate form the IC assembly according to any one of claims 26-29.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A device, comprising:
a semiconductor substrate;
a first transistor in a first layer over the semiconductor substrate; and
a second transistor in a second layer over the semiconductor substrate, the second layer different from the first layer, where the second transistor is a thin-film transistor.

2. The device according to claim 1, wherein the second transistor includes a first source/drain (S/D) electrode, a second S/D electrode, a channel material, a gate electrode, and a gate dielectric between the gate electrode and the channel material.

3. The device according to claim 2, wherein:
the first S/D electrode and the second S/D electrode of the second transistor are in a first sub-layer of the second layer, the channel material of the second transistor is in a second sub-layer of the second layer, and the gate electrode of the second transistor is in a third sub-layer of the second layer, and
the second sub-layer is between the first sub-layer and the third sub-layer.

4. The device according to claim 3, wherein the first sub-layer is between the second sub-layer and the first layer.

5. The device according to claim 3, wherein the third sub-layer is between the second sub-layer and the first layer.

6. The device according to claim 2, wherein:
the first transistor includes a first S/D electrode, a second S/D electrode, a channel material, a gate electrode, and a gate dielectric between the gate electrode and the channel material of the first transistor.

7. The device according to claim 6, wherein:
the device further includes a third transistor in the first layer, the third transistor including a first S/D electrode, a second S/D electrode, a channel material, a gate electrode, and a gate dielectric between the gate electrode and the channel material of the third transistor, and
the second S/D electrode of the second transistor is electrically continuous with the first S/D electrode of the third transistor.

8. The device according to claim 2, wherein:
the first transistor includes a first S/D electrode, a second S/D electrode, a channel material, a gate electrode, and a gate dielectric between the gate electrode and the channel material of the first transistor, and
the gate electrode of the second transistor is electrically continuous with the gate electrode of the first transistor.

9. The device according to claim 2, wherein the channel material of the second transistor is between one of the first S/D electrode and the second S/D electrode of the second transistor and the gate electrode of the second transistor.

10. The device according to claim 9, wherein each of the first S/D electrode, the second S/D electrode, and the gate electrode of the second transistor are electrically connected to at least one of a respective conductive via and a respective conductive line.

11. The device according to claim 2, wherein the first S/D electrode or the second S/D electrode of the second transistor includes a metal.

12. The device according to claim 2, wherein the first S/D electrode or the second S/D electrode of the second transistor includes a semiconductor and an n-type dopant.

13. The device according to claim 2, wherein the channel material of the second transistor includes one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, and black phosphorus.

14. The device according to claim 2, further comprising:
a storage element coupled to the first S/D electrode or the second S/D electrode of the second transistor.

15. The device according to claim 14, wherein the storage element includes a resistive random access memory (RRAM) element, a dynamic random access memory (DRAM) element, or a magnetic random access memory (MRAM) element.

16. A device, comprising:
a semiconductor substrate;
a thin-film transistor in a layer over the semiconductor substrate, the thin-film transistor being a bottom-gate transistor;
one or more interconnect layers above the layer of the thin-film transistor; and
one or more interconnect layers below the layer of the thin-film transistor.

17. The device according to claim 16, wherein the thin-film transistor includes a first source/drain (S/D) electrode, a second S/D electrode, a channel material, a gate electrode, and a gate dielectric between the gate electrode and the channel material, and wherein the device further includes a storage element coupled to the first S/D electrode or the second S/D electrode of the thin-film transistor.

18. The device according to claim 17, further comprising other circuitry, wherein the thin-film transistor is configured to connect the storage element to, or disconnect the storage element from, the other circuitry depending on a voltage applied to the gate electrode of the thin-film transistor.

19. The device according to claim 16, wherein the thin-film transistor includes first source/drain (S/D) electrode, a second S/D electrode, a channel material, a gate electrode, and a gate dielectric between the gate electrode and the channel material, and wherein the device further includes an other transistor coupled to the first S/D electrode or the second S/D electrode of the thin-film transistor, and further includes other circuitry, where the thin-film transistor is configured to connect the other transistor to, or disconnect the other transistor from, the other circuitry depending on a voltage applied to the gate electrode of the thin-film transistor.

20. A method of operating an electronic device, the method comprising:
applying a first voltage to a gate electrode of a thin-film transistor to connect a first circuit element to a second circuit element; and
applying a second voltage to the gate electrode of the thin-film transistor to disconnect the first circuit element from the second circuit element,
wherein the electronic device includes at least one interconnect layer between the thin-film transistor and a semiconductor substrate.

21. The method according to claim 20, wherein the thin-film transistor, the first circuit element, the second circuit element, and the at least one interconnect layer are included in a single die.

22. An integrated circuit (IC) assembly, comprising:
a die, including a thin-film transistor in a first layer of the die, one or more interconnect layers above the first layer, one or more interconnect layers below the first layer, and conductive contacts at a first face of the die; and
a further IC element,
wherein the conductive contacts at the first face of the die are electrically coupled to conductive contacts of the further IC element.

23. The IC assembly according to claim 22, wherein the die includes a reconfigurable interconnect arrangement.

24. The IC assembly according to claim 22, wherein the thin-film transistor is a bottom-gate transistor.

25. The IC assembly according to claim 22, wherein the further IC element is one of an interposer, a circuit board, a flexible board, or a package substrate.
